(19) United States
(12) Patent Application Publication
(10) Pub. No.: US 2022/0410735 A1
(43) Pub. Date: Dec. 29, 2022

(54) NOVEL CHARGING PILE CONNECTION BOX

(71) Applicant: Peng Su, Hangzhou (CN)

(72) Inventor: Peng Su, Hangzhou (CN)

(21) Appl. No.: 17/385,947

(22) Filed: Jul. 27, 2021

(30) Foreign Application Priority Data
Jun. 24, 2021 (CN) 20212141867.8

(51) Int. Cl. B60L 53/16; H05K 5/06

(52) U.S. Cl. CPC B60L 53/16; H05K 5/061; H05K 5/069; H02J 7/0042

(57) ABSTRACT

The invention relates to the electricity field, in particular to a novel charging pile connection box, comprising connection box, a connection hole arranged on outer wall of the connection box, a first mounting piece provided inside the connection box, a gasket provided outside the connection box, and a second mounting piece, a screw, the hole wall of the connection hole is provided with a notch, before preparing for connection, the user looses the screw with a screwdriver, disassembles the second mounting piece, the gasket and the first mounting piece in turn, and then disassembles the connection box and takes out the first mounting piece that falls inside the connection box.

### TECHNICAL FIELD

The invention relates to the electricity field, in particular to a novel charging pile connection box.

### BACKGROUND ART

In recent years, the photovoltaic industry and the electric vehicle industry have developed in full swing, and the charging pile industry is a pioneer in related industries, charging piles expand rapidly and have extensive application scenarios, various charging piles have been designed and the scenarios include but are not limited to: provide charging ports for electric cars or touring cars, and provide emergency power supply ports for residences and other places. Due to different occasions and environments, each charging pile has its own characteristics, when designing the prior wall-mounted charging pile equipment, the charging pile and the connection box are arranged separately, the mainstream connection boxes on the market adopt stamping to reserve the connection hole in the box wall position, when installing and using, the baffle needs to be punched through and removed along the indentation line, however, the connection box shell is mostly solid metal, which is not easy to damage, therefore, it is easy to cause the connection box body deformation or even damage, which seriously affects the aesthetics and ease of use.

### SUMMARY OF THE INVENTION

The invention aims to solve technical problems mentioned above by providing a novel charging pile connection box.

In order to solve above technical problems, the technical scheme provided by the invention is a novel charging pile connection box, comprising a connection box, a connection hole arranged on outer wall of the connection box, a first mounting piece provided inside the connection box, a gasket provided outside the connection box, and a second mounting piece, a screw, the hole wall of the connection hole is provided with a notch, the edge of the first mounting piece is provided with a protrusion connected with the notch, and the center of the first mounting piece is provided with a first threaded hole connected with a screw, the center of the gasket is provided with a through hole, and the center of the second mounting piece is provided with a boss connected with the through hole, the center of the boss is provided with a second threaded hole.

As an improvement, one side of the boss close to the screw is provided with a groove for placing the screw nut.

As an improvement, the gasket is made of rubber material.

Compared with the prior art, the invention has the advantages that the structure is simple and practical, and the wiring is easy to install, and the second mounting piece for encapsulating the connection hole is opened by removing the screw, thereby avoiding the deformation and damage of the connection box caused by hammering during the opening.

### BRIEF DESCRIPTION OF ACCOMPANYING DRAWINGS

FIG. 1 shows the external structure of the connection box;

FIG. 2 shows the first perspective of connection hole parts decomposition;

FIG. 3 shows the second perspective of connection hole parts decomposition.

In the accompanying drawings: 1 refers to connection box, 2 refers to connection hole, 201 refers to notch, 3 refers to first mounting piece, 301 refers to protrusion, 302 refers to first threaded hole, 4 refers to gasket, 401 refers to through hole, 5 refers to second mounting piece, 501 refers to boss, 502 refers to second threaded hole, 6 refers to screw.

### SPECIFIC EMBODIMENTS OF THE INVENTION

The following is a further detailed description of a novel charging pile connection box of the invention based on the accompanying drawings.

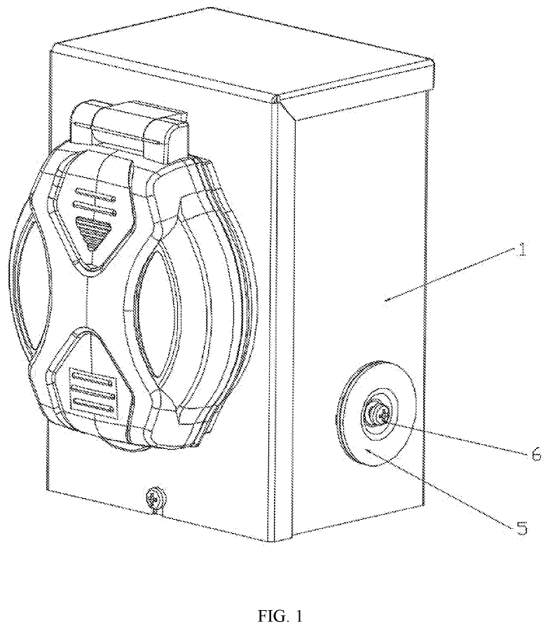

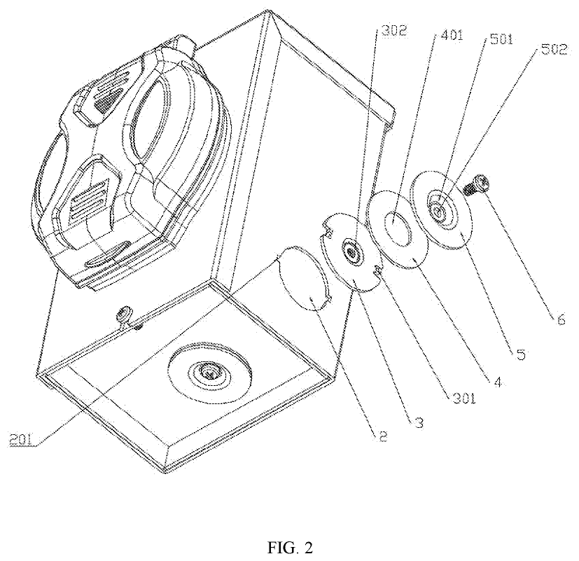

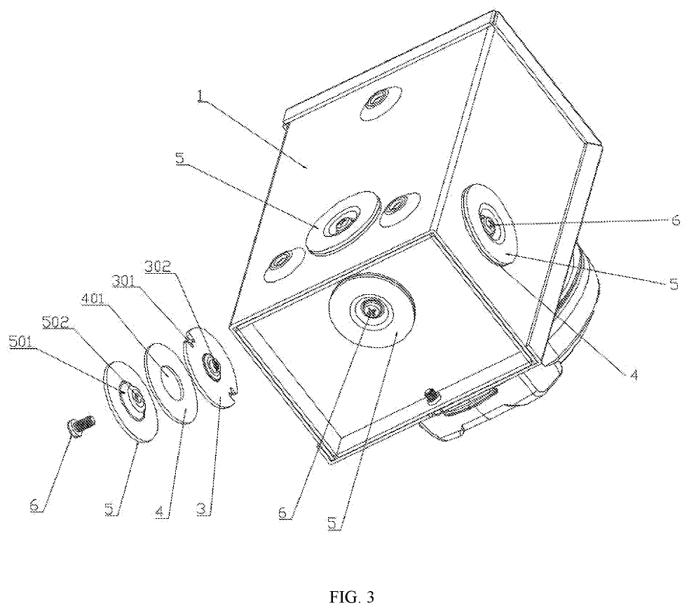

As shown in FIG. 1-3, a novel charging pile connection box, comprising a connection box 1, a connection hole 2 arranged on outer wall of the connection box 1, a first mounting piece 3 provided inside the connection box 1, a gasket 4 provided outside the connection box 1, and a second mounting piece 5, a screw 6, the hole wall of the connection hole 2 is provided with a notch 201, the edge of the first mounting piece 3 is provided with a protrusion 301 connected with the notch 201, and the center of the first mounting piece 3 is provided with a first threaded hole 302 connected with a screw 6, the center of the gasket 4 is provided with a through hole 401, and the center of the second mounting piece 5 is provided with a boss 501 connected with the through hole 401, the center of the boss 501 is provided with a second threaded hole 502.

As a preferred embodiment of the invention, one side of the boss 501 close to the screw 6 is provided with a groove for placing the screw 6 nut.

As a preferred embodiment of the invention, the gasket 4 is made of rubber material.

In the actual implementation of the invention, before preparing for connection, the user looses the screw 6 with a screwdriver, disassembles the second mounting piece 5, the gasket 4 and the first mounting piece 3 in turn, and then disassembles the connection box 1 and takes out the first mounting piece 3 that falls inside the connection box 1.

The invention and embodiments thereof are described above, and the description is not restrictive, what is shown in the drawings is only one of the embodiments of the invention, and the actual structure is not limited thereto. In genera, the invention has many functions to explore and expand, the person those skilled in the art can continue to research and explore cooperation without departing from the purpose of the invention. Any designed structural modes and embodiments similar to the technical solution without being creative, all belong to the protection scope of the invention.

1. A novel charging pile connection box, comprising a connection box (1), a connection hole (2) arranged on outer wall of the connection box (1), a first mounting piece (3) provided inside the connection box (1), a gasket (4) provided outside the connection box (1), and a second mounting piece (5), a screw (6), the hole wall of the connection hole (2) is provided with a notch (201), the edge of the first mounting piece (3) is provided with a protrusion (301) connected with the notch (201), and the center of the first mounting piece (3) is provided with a first threaded hole (302) connected with a screw (6), the center of the gasket (4) is provided with a through hole (401), and the center of the second mounting piece (5) is provided with a boss (501) connected with the through hole (401), the center of the boss (501) is provided with a second threaded hole (502).

2. The novel charging pile connection box of claim 1, one side of the boss (501) close to t screw (6) is provided with a groove for placing the screw (6) nut.

3. The novel charging pile connection box of claim 1, the gasket (4) is made of rubber material.
